(19) United States
(12) Patent Application Publication
(10) Pub. No.: US 2025/0158610 A1
(43) Pub. Date: May 15, 2025

(54) CIRCUIT ARRANGEMENT FOR ACTUATING A LARGE-AREA CAPACITIVE LOAD THAT IS TO BE OPERATED WITH AN AC VOLTAGE AND METHOD FOR OPERATING SUCH A CIRCUIT ARRANGEMENT

(71) Applicant: Continental Automotive Technologies GmbH, Hannover (DE)

(72) Inventors: Johannes Knorr, Wien (AT); Christian Stöger, Wien (AT)

(73) Assignee: Continental Automotive Technologies GmbH, Hannover (DE)

(21) Appl. No.: 18/946,326

(22) Filed: Nov. 13, 2024

(30) Foreign Application Priority Data
Nov. 14, 2023 (DE) 10 2023 211 309.0

(51) Int. Cl. H03K 17/56; H03K 5/1252

(52) U.S. Cl. CPC H03K 17/56; H03K 5/1252

(57) ABSTRACT

A circuit arrangement for actuating a capacitive load with an AC voltage is described. The behavior of the capacitive load depends on the RMS value of the applied voltage. The circuit arrangement comprises a first and second actuation circuit for actuating a capacitive load, each generating a square-wave signal. The first actuation circuit connects to the first connection of the capacitive load, and the second actuation circuit connects to the second connection. A control circuit actuates both actuation circuits so that the square-wave signals are time-offset, thus applying an AC voltage to the capacitive load. Each actuation circuit comprises an actuatable square-wave signal generator, and a downstream filter circuit. A voltage follower fed by a centrally filtered supply voltage is connected to each filter circuit and is configured to reduce its own harmonics, eliminating the need for downstream filters for radio frequencies.

The disclosure relates to a circuit arrangement for actuating a large-area capacitive load that is to be operated with an AC voltage and that has a first connection and a second connection, the behavior of which load depends on the RMS value of the applied voltage, comprising a first actuation circuit and a second actuation circuit that are designed to generate a first and a second signal, respectively, which are optimized in terms of harmonics, wherein the output connection of the first actuation circuit is connected to the first connection of the large-area capacitive load and the output connection of the second actuation circuit is connected to the second connection of the large-area capacitive load, and comprising a control circuit that is designed to actuate the first actuation circuit and the second actuation circuit in such a way that the generated signals that are optimized in terms of harmonics are offset from one another in time, as a result of which an AC voltage is applied to the capacitive large-area load.

The disclosure also relates to a method for operating such a circuit arrangement.

DE 10 2017 220 749 A1 discloses such a circuit arrangement and such a method. In said document, the square-wave signals or the trapezoidal signals are generated by subcircuits in the form of DC/DC converters or DC/AC converters or else a single converter circuit with a voltage divider connected downstream. However, such converter circuits are complex, generate many harmonics that have to be filtered, and are therefore costly.

The large-area capacitive load may in particular be a PDLC (polymer-dispersed liquid crystal) glass. Such switchable glazing units are already used in vehicles, e.g. for sunroofs. An electrical switchable glazing unit (smart glass or smart glass panel) may be changed over between the “transparent” transparency state and the “darkened/turbid” transparency state by switching an AC voltage on and off. The AC voltage for a switchable glazing unit is referred to as an actuation voltage below. The following transparency states are possible in the currently available switchable glazing units that are able to be actuated by the actuation voltage: an actuation voltage of 0 V corresponds to the “darkened” state and a positive or negative actuation voltage corresponds to the “transparent/transmissive” state. The periodically alternating actuation voltage may be an AC voltage in the range of 60 V-100 V, 50 Hz-100 Hz (PDLC) and 100 V, 50 Hz-100 Hz (SPD). In this case, a switchable glazing unit acts in the circuit as a capacitive load having a capacitance that may have a value of 20 μF/m².

The primary behavior of such switchable glasses (e.g. the transparency of a PDLC glass) depends on the RMS voltage across this capacitance. In this case, an AC voltage that is optimized in terms of harmonics has to be used if a DC component must not be present.

In order to be able to control the effectiveness of the actuator (e.g. the opacity in PDLC glasses), the RMS value of the voltage has to be controlled. This is able to be achieved by way of phase gating control or phase chopping control, or by controlling the amplitude. DE 10 2017 220 749 A1 also discloses applying two DC voltages pulsing in a manner offset by up to 1800 having positive and negative 60 V to the capacitive load, where they produce a pulsed AC voltage of up to 120 Veff; the voltage at the load is to be controlled by the offset of the individual voltages. All of these solutions require harmonic filtering at the connections for the capacitive load.

Some actuators are not compatible with a DC component, which is why if there is a DC component in each half-cycle, the amplitude must be additionally controlled in order to be free of a DC component for an entire period. In the case of PDLC glasses, for example, this prevents the active layer from degrading and the glass from no longer functioning.

Such actuators should be actuated with little circuit, power and software complexity so as to implement the desired function with an economical product.

This object may be achieved in a circuit arrangement of the generic type by virtue of the first actuation circuit and the second actuation circuit in each case being formed with
a first actuatable square-wave signal generator and a second actuatable square-wave signal generator, respectively,
a first filter circuit and a second filter circuit connected downstream of the first square-wave signal generator and the second square-wave signal generator, respectively, by which filter circuit the gradient of the switching edges of a square-wave signal is set,
a first voltage follower and a second voltage follower connected downstream of the first filter circuit and the second filter circuit, respectively, the respective output connection of said voltage followers in each case forming an output connection of the first actuation circuit and the second actuation circuit, respectively, and said voltage followers in each case having a supply connection, wherein the supply connections are connected to a supply voltage via at least one EMC filter,
wherein the control circuit is designed to actuate the first square-wave signal generator and the second square-wave signal generator in such a way that the generated square-wave signals are offset from one another in time.

The object may also be achieved by a method for operating a described circuit arrangement, wherein the control circuit actuates the first square-wave signal generator and the second square-wave signal generator in such a way that a positive voltage is applied successively between the first connection and the second connection of the capacitive load(s) by the square-wave signals offset from one another in time, the first connection and the second connection of the capacitive load(s) are connected to one another and to the low potential of a filtered supply voltage, a negative voltage is applied between the first connection and the second connection of the capacitive load(s) and the first connection and the second connection of the capacitive load(s) are connected to one another and to the high potential of the filtered supply voltage, with the result that an AC voltage is applied to the capacitive load.

The concept behind this circuit arrangement and the method is that the connections of the actuator are not alternately periodically routed to a high potential and back to a ground potential so that the actuator is discharged if both terminals are connected to ground, but rather the actuator is discharged by the second connection being routed to the potential of the first connection. Charging in the positive direction is therefore achieved by routing the first (in the case of segmented actuators, the common) connection to a high potential, while the second connection remains connected to ground. The subsequent discharging of the actuator is then carried out by the second connection also being routed to the high potential. Charging in the negative direction is then achieved not by routing the second connection to a high potential, but by routing the first (in the case of segmented actuators, the common) connection to ground. Furthermore, the negative half-cycle is then discharged by subsequently routing the second connection to ground.

In this case, routing the connections to the voltages is achieved by non-switching output stages (voltage followers), with the result that at least one filter between the supply voltage and the actuation circuits is sufficient to also be able to actuate the large-area capacitive loads in an EMC-optimized manner because the design of the non-switching output stages (voltage followers) means that harmonics that are still relevant in radio frequencies are no longer able to occur. This principle results in multiple advantages.

Controlling output amplitudes in the case of variable loads (the conductivity of PDLC glasses thus changes greatly with the temperature) is always a critical issue and requires many SW resources in order to guide a half-wave generator (class D amplifier or switching regulator) in terms of time and correct amplitude, for example. It is much simpler to have only one time-based actuation method. In order to achieve this, the disclosure solves the problem such that the output stage is a voltage follower that is fed by an EMC-filtered supply voltage and that follows a simple square-wave signal, in particular from a computing unit, which is smoothed by way of a passive or an active filter. This means that the rhythm of the charging and discharging processes is determined by the computing unit and the voltage profile is determined exclusively by the circuit. Said voltage profile is therefore largely load-independent and does not require any harmonic filters at the output connections.

A first advantage may be that, on account of the filtered supply voltage for reducing the harmonics of the voltage source and the configuration as non-switching output stages, i.e. as analog voltage followers, no harmonic filters are required at the outputs, although the capacitive loads are usually connected to the circuit via unfavorably long cables and, due to their physical dimensions, themselves constitute high-efficiency antennas that transmit switching influences to the environment as radio interference very well.

A second advantage may be that the current for discharging the actuator does not have to be taken from the supply, but rather from the actuator itself, which is why only half as much energy is required. As a result, the efficiency is significantly increased and it is possible to implement the function not only more economically, but also more ecologically.

A third advantage may be that compensation that only changes the pulse width of the square-wave signals and not amplitudes may be carried out for actuators that have to be operated without a DC component. Thus, the compensation of DC components is also corrected by the rhythm and not by the voltage profile, which makes this easy to implement, in particular in the computing unit. The duty ratio of the first (or, for segmented actuators, common) connection is always 50%. The frequency of both connections must be identical so that no floating effects occur. It is also therefore possible to set the DC components in a targeted manner, if this were desired.

Advantageously, the first square-wave signal generator and second square-wave signal generator may be formed by a microcontroller. Many microcontrollers in the automotive sector provide such square-wave signals, sometimes with the possibility of pulse-width modulation.

In one advantageous embodiment of the first filter circuit and the second filter circuit, they are formed with a first switch unit and a second switch unit, respectively, wherein the switch units are each able to be actuated by the assigned first square-wave signal generator and second square-wave signal generator, respectively, and, depending on the level of the square-wave signal, switch a filtered supply voltage through to a first signal-forming filter and a second signal-forming filter, respectively. In this case, the first signal-forming filter and the second signal-forming filter may be formed with a series circuit comprising one or two RC filters, or else may be in the form of actuatable active filters.

This makes it possible to shape the switching edges of the voltages, which are applied to the connections of a capacitive load, purely in terms of circuitry without a large outlay on components in order to influence the current flow, for example, and to dispense with a subsequent harmonic filter.

In one development of the circuit arrangement, at least two capacitive loads may be actuated, wherein the first connections of the capacitive loads are connected to one another and to the first actuation circuit, wherein the circuit arrangement has a respective second actuation circuit for each capacitive load, wherein each second actuation circuit is connected to the second connection of an assigned capacitive load.

It is therefore possible to extend the circuit arrangement according to the disclosure in a simple manner with little outlay if a plurality of capacitive loads, for example a plurality of segments of smart glass, are intended to be actuated independently of one another, without having to use further filters.

The method according to the disclosure makes it possible to set or compensate for a DC voltage component in the generated AC voltage owing to different duty ratios of the signals of the first square-wave generator and the second square-wave generator.

In this way it may be ensured, on the one hand, that, in the case of a large-area capacitive load whose actuation voltage must not have a DC component, it is possible to compensate for said DC component by modulating the duty ratio of at least one of the two actuation signals. However, on the other hand, a desired DC voltage component may also be set in a targeted manner.

The disclosure is explained in more detail below based on an exemplary embodiment with the aid of figures, in which:

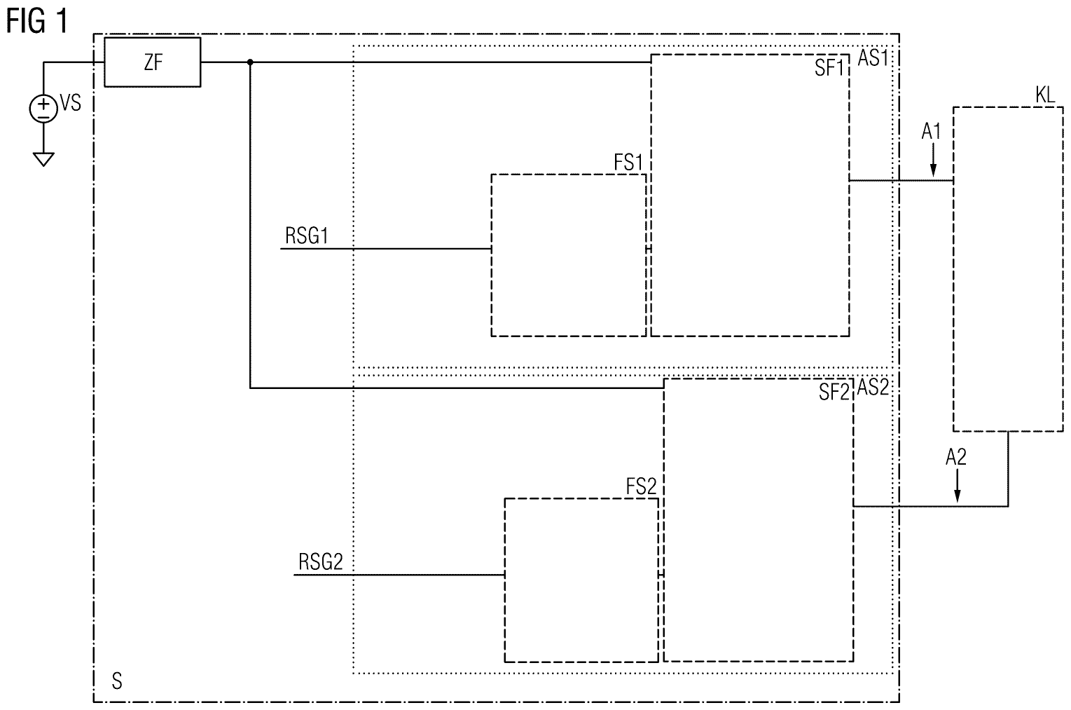

FIG. 1 shows a block diagram of an exemplary embodiment of a circuit arrangement according to the disclosure;

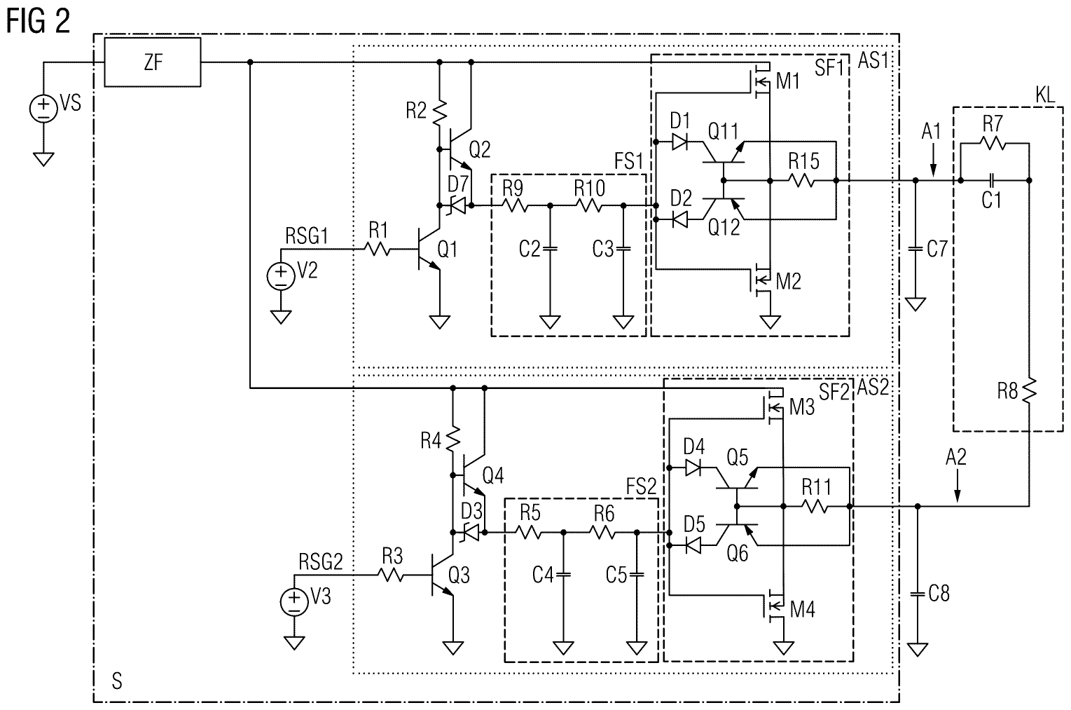

FIG. 2 shows a more detailed circuit diagram of an exemplary embodiment of a circuit arrangement according to the disclosure;

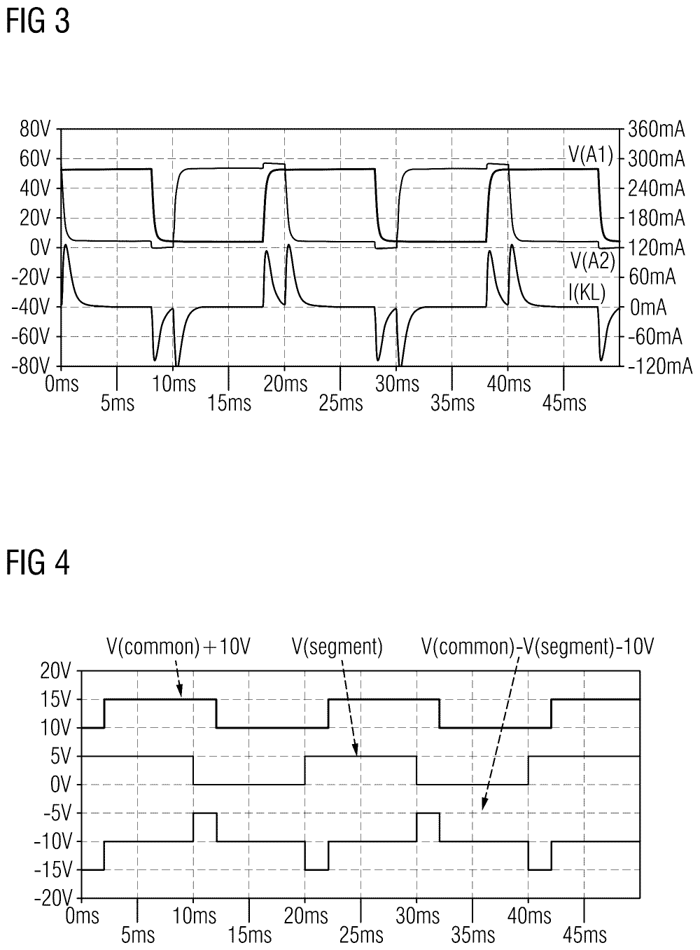

FIG. 3 shows a possible exemplary voltage profile and current profile at the output of the voltage followers;

FIG. 4 shows a first exemplary profile of the square-wave voltages and their differential voltage;

FIG. 5 shows a second exemplary profile of the square-wave voltages and their differential voltage;

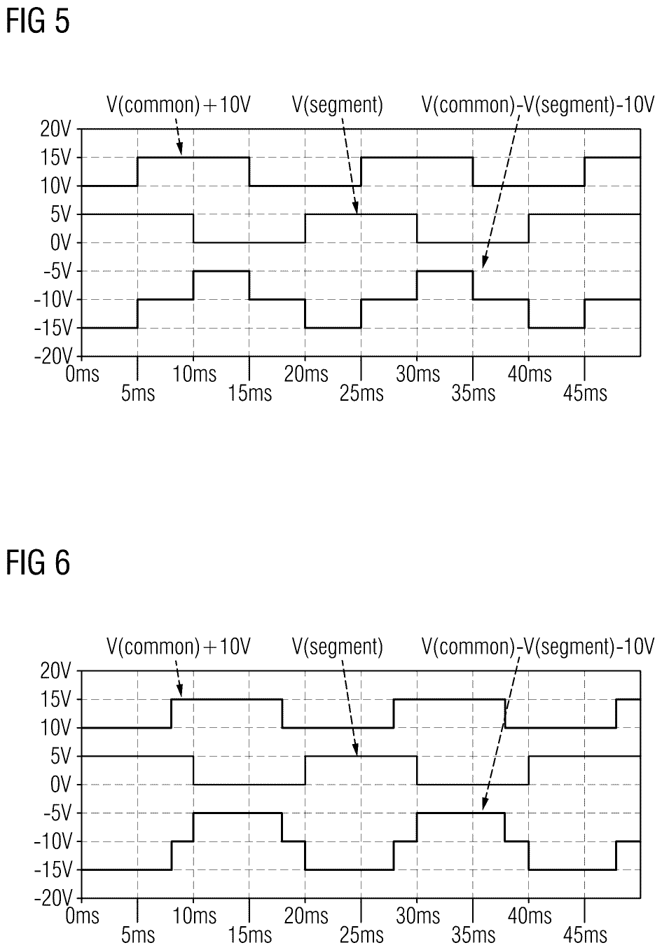

FIG. 6 shows a third exemplary profile of the square-wave voltages and their differential voltage;

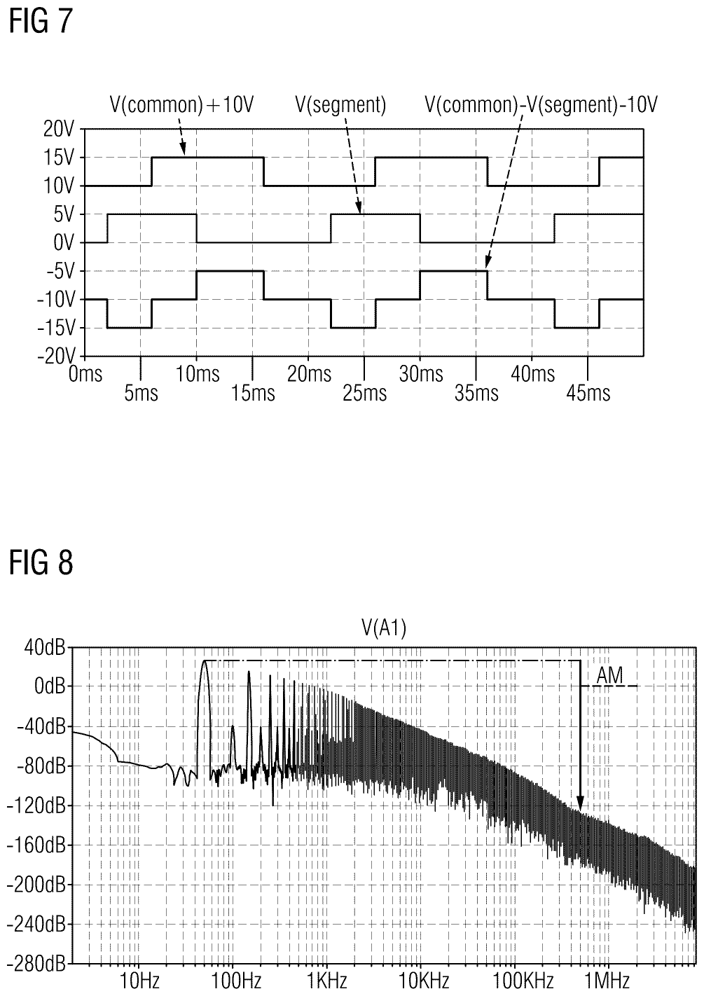

FIG. 7 shows a fourth exemplary profile of the square-wave voltages and their differential voltage in the case of an altered duty ratio of one of the square-wave voltages;

FIG. 8 shows the exemplary spectrum of the output of the non-switching output stage when actuated by a square-wave voltage of 50 Hz.

In the exemplary embodiment of FIG. 1 or 2, a capacitive load KL has a first connection A1 and a second connection A2. The capacitive load KL is shown using an equivalent circuit diagram that has a first capacitor C1, a seventh resistor R7 connected in parallel with said capacitor, and an eighth resistor R8 connected in series with this parallel circuit. The seventh resistor and the eighth resistor R7, R8 are parasitic resistances of the first capacitor C1, which essentially forms the capacitive load KL. The capacitive load may in particular be an actuatable glass that may be altered in terms of its opacity by the RMS value of an AC voltage.

The AC voltage is generated by two approximately trapezoidal voltages that are phase-shifted with respect to one another and applied to the connections of the capacitive load KL. The differential voltage of the two approximately trapezoidal voltages is then across the capacitive load KL.

This is illustrated in FIGS. 4 to 6, wherein only square-wave signals are shown here for reasons of simplification. In these figures, the upper curve in each case shows a first square-wave signal and the middle curve in each case shows a second square-wave signal. The two square-wave signals are phase-shifted differently with respect to one another in each of FIGS. 4 to 6. The lower curve in each case shows the differential signal that may be applied to the capacitive load KL as AC voltage. The phase shift sets the duty ratio of the AC voltage and therefore its RMS value.

According to the exemplary embodiment of a circuit arrangement according to FIGS. 1 and 2, the first square-wave signal and the second square-wave signal are generated by a first square-wave signal generator RSG1 and a second square-wave signal generator RSG2, respectively. Although the square-wave signal generators RSG1, RSG2 are shown as voltage sources V2, V3, they may advantageously be implemented by a microcontroller.

In the following, the circuit arrangement S is explained based on the first actuation circuit in the upper half of the illustration in FIG. 2, and the second actuation circuit is of identical design, as can easily be seen.

The first square-wave signal generator RSG1 actuates a first filter circuit FS1 via a first resistor R1. In the exemplary embodiment, the first filter circuit FS1 is formed with a series circuit comprising a second npn transistor Q2, a seventh diode D7 and a first npn transistor Q1, which is connected between the two poles of a supply voltage VS. The base connection of the second transistor Q2 is connected via a second resistor R2 to the collector connection of the second transistor Q2 and directly to the collector connection of the first transistor Q1.

The emitter connection of the second transistor Q2 is connected to the low potential of the supply voltage VS via a series circuit of a ninth resistor R9 and a second capacitor C2. Is connected to the low potential of the supply voltage VS via a series circuit of a tenth resistor R10 and a third capacitor C3. The connecting connection of the tenth resistor R10 and the third capacitor C3 forms the output connection of the first filter circuit FS1.

Depending on the level of the first square-wave signal generator RSG1, the first filter circuit FS1, as well as the second filter circuit FS2, therefore switch the potential of the supply voltage VS from the first npn transistor and the second npn transistor Q1, Q2 to a series circuit of two RC filters via the first switch unit, in order to incline the edges of the square-wave signal. The edge gradient may therefore be set by selecting the values of the resistors and capacitors of the first filter circuit FS1.

It is also possible to select an active filter, the filter properties of which may then be set, for example, by the microcontroller, which also provides the square-wave signals.

A first voltage follower SF1 is connected downstream of the first filter circuit FS1. Said voltage follower is formed with a series circuit comprising an n-channel field-effect transistor M1 and a p-channel field-effect transistor M2, which is connected between the poles of the supply voltage VS filtered by the central filter ZF. The gate connections of the two field-effect transistors M1, M2 are connected to the output connection of the first filter circuit FS1.

The connecting point of the two field-effect transistors M1 and M2 is connected via a fifteenth resistor R15 to an output connection of the first voltage follower SF1, which in turn is connected to the first connection A1 of the capacitive load KL.

The gate connection of the n-channel field-effect transistor M1 is connected to the output connection of the first voltage follower SF1 via a series circuit comprising a first, forward-biased diode D1 and an eleventh npn transistor Q11, and the gate connection of the p-channel field-effect transistor M2 is connected to the output connection of the first voltage follower SF1 via a series circuit comprising a second, reverse-biased diode D2 and a twelfth pnp transistor Q12. The base connections of the eleventh transistor and the twelfth transistor are connected to the connecting point of the two field-effect transistors M1 and M2.

The first actuation circuit AS1 described is therefore actuated by the first square-wave signal generator RSG1, which generates a first square-wave signal, as shown in the upper part of FIGS. 3 to 5. The first square-wave signal preferably has a duty ratio of 50%. The edge of the square-wave signal is inclined, as shown in FIG. 3, by the first filter circuit FS1 connected downstream. The output signal of the first filter circuit FS1 therefore has a trapezoidal shape.

This trapezoidal output signal of the first filter circuit FS1 is then supplied to the first voltage follower SF1, which merely carries out a current amplification, but retains the signal waveform and supplies same to the capacitive load KL.

In the same way, the second actuation circuit AS2 is formed with a second square-wave signal generator RSG2, a second filter circuit FS2 and a second voltage follower SF2, which have the same function. The second actuation circuit AS2 is connected to the second connection A2 of the capacitive load KL by the output of the second voltage follower SF2.

Using a control circuit (not shown), the two square-wave signals are generated so as to be phase-shifted and supplied as trapezoidal signals to the capacitive load KL, with the result that the desired AC voltage is applied thereto with the desired RMS value that is dependent on the phase offset.

If a DC component is also desired in the AC voltage, both a positive and a negative DC component may be set by changing the duty ratio of at least one of the square-wave signals; this is shown in FIG. 7.

In the same way, it is also possible to compensate for a DC component that may be present by adjusting the duty ratio.

The circuit arrangement S described is therefore a centrally filtered actuation stage or output stage for capacitive loads KL, which have to be operated with AC voltage and are controlled by the RMS value thereof, and may be implemented only by virtue of DC/DC converters or DC/AC converters not being used to actuate the connections A1, A2 of the capacitive load KL.

The connections of the capacitive load KL are not routed alternately with a half-cycle, but are interleaved in such a way that the energy required to discharge the load is not taken from the supply of the circuit, but from the load itself.

The RMS value of the AC voltage is determined by the phase offset of the control signals and therefore subsequently the voltages across the connections of the load. This means that the amplitude of the output voltages does not have to be tracked.

The freedom from a DC component may be achieved by changing the duty ratio of an actuation signal or a DC component may be achieved by changing the duty ratio of an actuation signal. This DC component may be positive or negative.

The central filter ZF may subsequently be formed with respect to the supply voltage VS jointly for all actuation circuits, or separately for each actuation circuit, with less power then having to be filtered.

The actuation or output stage may be formed by MOSFETs or by bipolar transistors. It may also be formed by electromechanical actuators or by amplifiers in the general sense.

The control of the current through the output stage may be defined by passive or active filters or by a variable gain of an amplifier.

The controlled actuator may have a capacitive or resistive behavior.

The controlled actuator may also be actuated with an AC current instead of an AC voltage.

With a suitable design of the circuit, it is easily possible to achieve over 150 dB attenuation for the AM radio band in relation to the actuation voltage, which means that a filter at the output is no longer required.

1. A circuit arrangement for actuating a large-area capacitive load for operating with an AC voltage, the capacitive load comprising a first connection and a second connection, the capacitive load behavior being dependent on an RMS value of applied voltage,
further comprising a first actuation circuit and a second actuation circuit that are designed to generate a first signal and a second signal, respectively, which are optimized in terms of harmonics,
wherein an output connection of the first actuation circuit is connected to the first connection of the capacitive load and an output connection of the second actuation circuit is connected to the second connection of the capacitive load,
and further comprising a control circuit configured to actuate the first actuation circuit and the second actuation circuit so that the generated signals that are optimized in terms of harmonics are offset from one another in time, resulting in AC voltage being applied to the capacitive load, wherein:
the first actuation circuit and the second actuation circuit each comprise a first actuatable square-wave signal generator and a second actuatable square-wave signal generator, respectively,
a first filter circuit and a second filter circuit is connected downstream of the first square-wave signal generator and the second square-wave signal generator, respectively, whereby a gradient of switching edges of a square-wave signal is set,
a first voltage follower and a second voltage follower connected downstream of the first filter circuit and the second filter circuit, respectively, the respective output connection of said voltage followers respectively forming an output connection of the first actuation circuit and the second actuation circuit, and said voltage followers respectively comprising a supply connection, wherein the supply connections are connected to a supply voltage via at least one EMC filter,
wherein the control circuit is configured to actuate the first square-wave signal generator and the second square-wave signal generator so that the generated square-wave signals are offset from one another in time.

2. The circuit arrangement as claimed in claim 1, wherein the first square-wave signal generator and the second square-wave signal generator comprise a microcontroller.

3. The circuit arrangement as claimed in claim 2, wherein the first filter circuit and the second filter circuit comprise a first switch unit and a second switch unit, respectively, wherein the switch units are each configured to be actuated by the respective first square-wave signal generator and second square-wave signal generator, respectively, and, depending on a level of the square-wave signal, switch EMC-filtered supply voltage through to a first signal-forming filter and a second signal-forming filter, respectively.

4. The circuit arrangement as claimed in claim 3, wherein the first signal-forming filter and the second signal-forming filter comprise a series circuit comprising two RC filters.

5. The circuit arrangement as claimed in claim 3, wherein the first signal-forming filter and the second signal-forming filter are actuatable active filters.

6. The circuit arrangement as claimed in claim 2, wherein a separate EMC filter is provided for each actuation circuit connected to an output.

7. The circuit arrangement as claimed in claim 2, wherein at least two capacitive loads are configured to be actuated, wherein the first connections of the capacitive loads are connected to one another and to the first actuation circuit, wherein the circuit arrangement has a respective second actuation circuit for each capacitive load, wherein each second actuation circuit is connected to the second connection of an assigned capacitive load.

8. The circuit arrangement as claimed in claim 1, wherein the first filter circuit and the second filter circuit comprise a first switch unit and a second switch unit, respectively, wherein the switch units are each configured to be actuated by the respective first square-wave signal generator and second square-wave signal generator, respectively, and, depending on a level of the square-wave signal, switch EMC-filtered supply voltage through to a first signal-forming filter and a second signal-forming filter, respectively.

9. The circuit arrangement as claimed in claim 8, wherein the first signal-forming filter and the second signal-forming filter comprise a series circuit comprising two RC filters.

10. The circuit arrangement as claimed in claim 9, wherein a separate EMC filter is provided for each actuation circuit connected to an output.

11. The circuit arrangement as claimed in claim 9, wherein at least two capacitive loads are configured to be actuated, wherein the first connections of the capacitive loads are connected to one another and to the first actuation circuit, wherein the circuit arrangement has a respective second actuation circuit for each capacitive load, wherein each second actuation circuit is connected to the second connection of an assigned capacitive load.

12. The circuit arrangement as claimed in claim 8, wherein the first signal-forming filter and the second signal-forming filter are actuatable active filters.

13. The circuit arrangement as claimed in claim 12, wherein a separate EMC filter is provided for each actuation circuit connected to an output.

14. The circuit arrangement as claimed in claim 12, wherein at least two capacitive loads are configured to be actuated, wherein the first connections of the capacitive loads are connected to one another and to the first actuation circuit, wherein the circuit arrangement has a respective second actuation circuit for each capacitive load, wherein each second actuation circuit is connected to the second connection of an assigned capacitive load.

15. The circuit arrangement as claimed in claim 1, wherein a separate EMC filter is provided for each actuation circuit connected to an output.

16. The circuit arrangement as claimed in claim 1, wherein at least two capacitive loads are configured to be actuated, wherein the first connections of the capacitive loads are connected to one another and to the first actuation circuit, wherein the circuit arrangement has a respective second actuation circuit for each capacitive load, wherein each second actuation circuit is connected to the second connection of an assigned capacitive load.

17. A method for operating a circuit arrangement as claimed in claim 1, wherein the control circuit actuates the first square-wave signal generator and the second square-wave signal generator so that a positive voltage is applied successively between the first connection and the second connection of the capacitive load by the square-wave signals offset from one another in time, the first connection and the second connection of the capacitive load are connected to one another and to low potential of filtered supply voltage, a negative voltage is applied between the first connection and the second connection of the capacitive load and the first connection and the second connection of the capacitive load are connected to one another and to high potential of the filtered supply voltage, resulting in an AC voltage being applied to the capacitive load.

18. The method as claimed in claim 17, wherein duration of the positive voltage and the negative voltage, and therefore the RMS value of the AC voltage, is determined by an extent of the offset of the two square-wave signals.

19. The method as claimed in claim 18, wherein a DC voltage component in the AC voltage is set or compensated for based on different duty ratios of the signals of the first square-wave generator and the second square-wave generator.

20. The method as claimed in claim 17, wherein a DC voltage component in the AC voltage is set or compensated for based on different duty ratios of the signals of the first square-wave generator and the second square-wave generator.
